(19) United States
(12) Patent Application Publication
(10) Pub. No.: US 2026/0129742 A1
(43) Pub. Date: May 7, 2026

(54) PRINTED CIRCUIT BOARD ASSEMBLY AND ELECTRONIC DEVICE COMPRISING SAME

(71) Applicant: Samsung Electronics Co., Ltd., Suwon-si (KR)

(72) Inventors: Yoonhee CHANG, Suwon-si (KR); Min PARK, Suwon-si (KR); Jeonggen YOON, Suwon-si (KR); Myungjun KIM, Suwon-si (KR); Jinhyeok PARK, Suwon-si (KR); Jieun HWANG, Suwon-si (KR); Junghoon KIM, Suwon-si (KR); Jongdo PARK, Suwon-si (KR); Jonggeun YOON, Suwon-si (KR); Haejin LEE, Suwon-si (KR)

(21) Appl. No.: 19/438,039

(22) Filed: Dec. 31, 2025

Related U.S. Application Data
(63) Continuation of application No. PCT/KR2024/008619, filed on Jun. 21, 2024.

(30) Foreign Application Priority Data
Jul. 31, 2023 (KR) 10-2023-0099938
Oct. 23, 2023 (KR) 10-2023-0141831

(51) Int. Cl. H05K 1/02; H05K 1/181; H05K 3/303

(52) U.S. Cl. CPC H05K 1/0209; H05K 1/0216; H05K 1/181; H05K 3/303; H05K 2201/066; H05K 2201/10371

(57) ABSTRACT

A printed circuit board assembly is provided. The printed circuit board assembly includes a printed circuit board (PCB), a plurality of electronic components configured to be mounted on a first surface of the PCB, a first shielding member configured to cover the plurality of electronic components, and a heat transfer member received within the first shielding member, having a portion disposed in a space formed between the plurality of electronic components, and configured to be thermally deformable.

### CROSS-REFERENCE TO RELATED APPLICATION(S)

This application is a continuation application, claiming priority under 35 U.S.C. § 365(c), of an International application No. PCT/KR2024/008619, filed on Jun. 21, 2024, which is based on and claims the benefit of a Korean patent application number 10-2023-0099938, filed on Jul. 31, 2023, in the Korean Intellectual Property Office, and of a Korean patent application number 10-2023-0141831, filed on Oct. 23, 2023, in the Korean Intellectual Property Office, the disclosure of each of which is incorporated by reference herein in its entirety.

### BACKGROUND

### 1. Field

The disclosure relates to a printed circuit board assembly and an electronic device including the same.

### 2. Description of Related Art

Electronic devices, such as smartphones and tablet computers, are becoming an important means of rapidly changing information transfer. These electronic devices facilitate users' tasks through a graphical user interface (GUI) environment using a touchscreen and provide various multimedia based on a web environment.

Electronic devices are equipped with various communication components or electronic components to provide various functions. For example, an electronic device provides a music playback function using stereo sound by having stereo speaker modules equipped thereon. Further, the electronic device has a camera module to provide a photographing function. Also, the electronic device provides a communication function with other electronic devices through a network by a communication module equipped therein.

To achieve higher-performance electronic devices, a plurality of electronic components is mounted in a limited printed circuit board space.

The above information is presented as background information only to assist with an understanding of the disclosure. No determination has been made, and no assertion is made, as to whether any of the above might be applicable as prior art with regard to the disclosure.

### SUMMARY

Electronic devices may experience increased heat generation from mounted components due to slimmer body designs and use of high-specification application processors (APs).

Aspects of the disclosure are to address at least the above-mentioned problems and/or disadvantages and to provide at least the advantages described below. Accordingly, an aspect of the disclosure is to provide a printed circuit board assembly having an additional heat dissipation structure.

Additional aspects will be set forth in part in the description which follows and, in part, will be apparent from the description, or may be learned by practice of the presented embodiments.

In accordance with an aspect of the disclosure, a printed circuit board assembly is provided. The printed circuit board assembly includes a printed circuit board (PCB), a plurality of electronic components configured to be mounted on a first surface of the PCB, a first shielding member configured to cover the plurality of electronic components, and a heat transfer member received within the first shielding member, having a portion disposed in a space formed between the plurality of electronic components, and configured to be thermally deformable.

In accordance with another aspect of the disclosure, an electronic device is provided. The electronic device includes a housing, a display, and a printed circuit board assembly disposed within the housing, wherein the printed circuit board assembly includes a printed circuit board (PCB), a plurality of electronic components mounted on a first surface of the PCB, a first shielding member provided to cover the plurality of electronic components, and a heat transfer member received within the first shielding member, having at least a portion disposed in a space formed between the plurality of electronic components, and configured to be thermally deformable.

In accordance with another aspect of the disclosure, a manufacturing method of a printed circuit board assembly is provided. The manufacturing method includes disposing a heat transfer member configured to be thermally deformable on a plurality of electronic components mounted on a printed circuit board (PCB), disposing a first shielding member to cover the heat transfer member and the plurality of electronic components, and pressing the first shielding member with an upper jig including a heating block.

According to various embodiments proposed in the disclosure, the printed circuit board assembly has enhanced heat dissipation performance for a main heat generating element such as an AP.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a view illustrating an electronic device in a network environment according to an embodiment of the disclosure;

FIG. 2A is a front perspective view illustrating an electronic device according to an embodiment of the disclosure;

FIG. 2B is a rear perspective view illustrating the electronic device of FIG. 2A according to an embodiment of the disclosure;

FIG. 3 is an exploded perspective view illustrating an electronic device according to an embodiment of the disclosure;

FIG. 4 is a plan view illustrating a printed circuit board assembly according to an embodiment of the disclosure;

FIG. 5 is a cross-sectional view illustrating a printed circuit board assembly according to an embodiment of the disclosure;

FIG. 6 is a perspective view illustrating a thermal compression device according to an embodiment of the disclosure;

FIGS. 7A and 7B are cross-sectional views illustrating a process of thermally compressing a first shielding member and a first heat transfer member according to various embodiments of the disclosure;

FIG. 8 is a flowchart illustrating a manufacturing method of a printed circuit board assembly according to an embodiment of the disclosure;

FIG. 9 is an experimental example illustrating temperature changes of a first heat transfer member over time in case of thermally compressing a first shielding member and a first heat transfer member according to an embodiment of the disclosure;

FIG. 10 is a graph for describing enhanced operational performance of a main heat generating element mounted on a printed circuit board assembly according to an embodiment of the disclosure;

FIGS. 11A and 11B are views illustrating shape changes in case that a first heat transfer member is thermally compressed according to various embodiments of the disclosure;

FIG. 12 is a plan view illustrating a printed circuit board assembly according to an embodiment of the disclosure;

FIG. 13 is a cross-sectional view illustrating a printed circuit board assembly according to an embodiment of the disclosure;

FIG. 14 is a cross-sectional view illustrating a printed circuit board assembly according to an embodiment of the disclosure;

FIG. 15 is a cross-sectional view illustrating a printed circuit board assembly according to an embodiment of the disclosure; and

FIG. 16 is a cross-sectional view illustrating a printed circuit board assembly according to an embodiment of the disclosure.

Throughout the drawings, it should be noted that like reference numbers are used to depict the same or similar elements, features, and structures.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art to will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a wireless fidelity (Wi-Fi) chip, a Bluetooth® chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

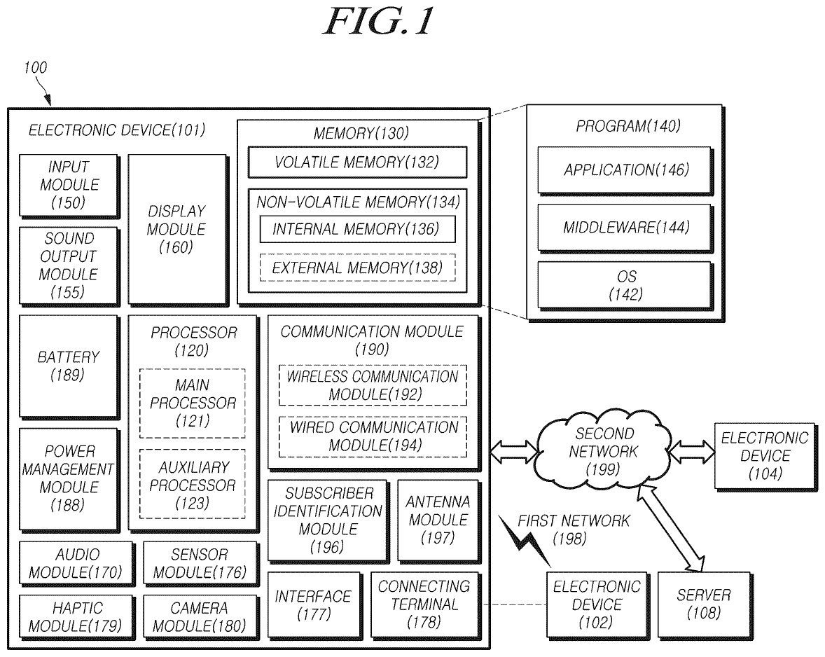

FIG. 1 is a block diagram illustrating an electronic device in a network environment according to an embodiment of the disclosure.

Referring to FIG. 1, the electronic device 101 in the network environment 100 may communicate with at least one of an electronic device 102 via a first network 198 (e.g., a short-range wireless communication network), or an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In an embodiment, at least one (e.g., the connecting terminal 178) of the components may be omitted from the electronic device 101, or one or more other components may be added in the electronic device 101. According to an embodiment, some (e.g., the sensor module 176, the camera module 180, or the antenna module 197) of the components may be integrated into a single component (e.g., the display module 160).

The processor 120 may execute, for example, software (e.g., the program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, in case that the electronic device 101 includes the main processor 121 and the auxiliary processor 123, the auxiliary processor 123 may be configured to use lower power than the main processor 121 or to be specified for a designated function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. The artificial intelligence model may be generated via machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134. Further, the non-volatile memory may include internal memory 136 or external memory 138.

The program 140 may be stored in the memory 130 as software, and may include, for example, an operating system (OS) 142, middleware 144, or an application 146.

The input module 150 may receive a command or data to be used by other component (e.g., the processor 120) of the electronic device 101, from the outside (e.g., a user) of the electronic device 101. The input module 150 may include, for example, a microphone, a mouse, a keyboard, keys (e.g., buttons), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor configured to detect a touch, or a pressure sensor configured to measure the intensity of a force generated by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., the electronic device 102) directly (e.g., wiredly) or wirelessly coupled with the electronic device 101.

The sensor module 176 may detect an operation state (e.g., power or temperature) of the electronic device 101 or an external environmental state (e.g., the user's state), and then generate an electrical signal or data value corresponding to the detected state. According to an embodiment, the sensor module 176 may include, for example, a gesture sensor, a gyro sensor, an atmospheric pressure sensor, a magnetic sensor, an accelerometer, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, an HDMI connector, a USB connector, an SD card connector, or an audio connector (e.g., a headphone connector).

The haptic module 179 may convert an electrical signal into a mechanical stimulus (e.g., a vibration or motion) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wiredly) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device 104 via a first network 198 (e.g., a short-range communication network, such as Bluetooth^{TM}, wireless-fidelity (Wi-Fi) direct, or infrared data association (IrDA)) or a second network 199 (e.g., a long-range communication network, such as a legacy cellular network, a fifth generation (5G) network, a next-generation communication network, the Internet, or a computer network (e.g., local area network (LAN) or wide area network (WAN)). These various types of communication modules may be implemented as a single component (e.g., a single chip), or may be implemented as multi components (e.g., multi chips) separate from each other. The wireless communication module 192 may identify or authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a fourth generation (4G) network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the millimeter-wave (mmWave) band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device). According to an embodiment, the antenna module 197 may include one antenna including a radiator formed of a conductor or conductive pattern formed on a substrate (e.g., a printed circuit board (PCB)). According to an embodiment, the antenna module 197 may include a plurality of antennas (e.g., an antenna array). In this case, at least one antenna appropriate for a communication scheme used in a communication network, such as the first network 198 or the second network 199, may be selected from the plurality of antennas by, e.g., the communication module 190. The signal or the power may then be transmitted or received between the communication module 190 and the external electronic device via the selected at least one antenna. According to an embodiment, other parts (e.g., radio frequency integrated circuit (RFIC)) than the radiator may be further formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. The external electronic devices 102 or 104 each may be a device of the same or a different type from the electronic device 101. According to an embodiment, all or some of operations to be executed at the electronic device 101 may be executed at one or more of the external electronic devices 102 or 104 or the server 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an Internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

The electronic device according to various embodiments of the disclosure may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

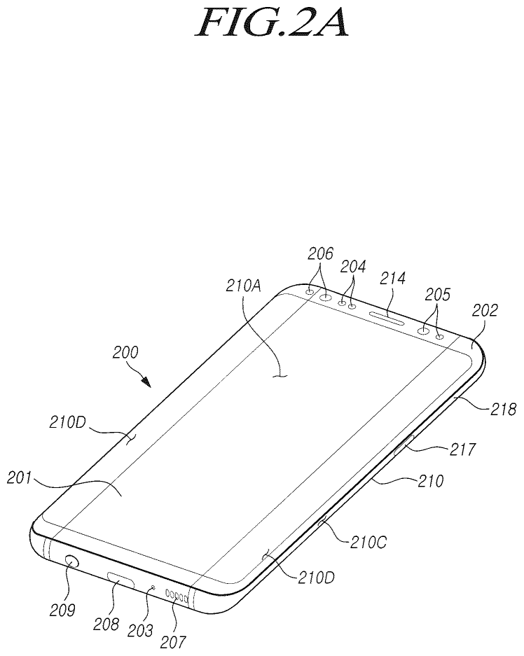

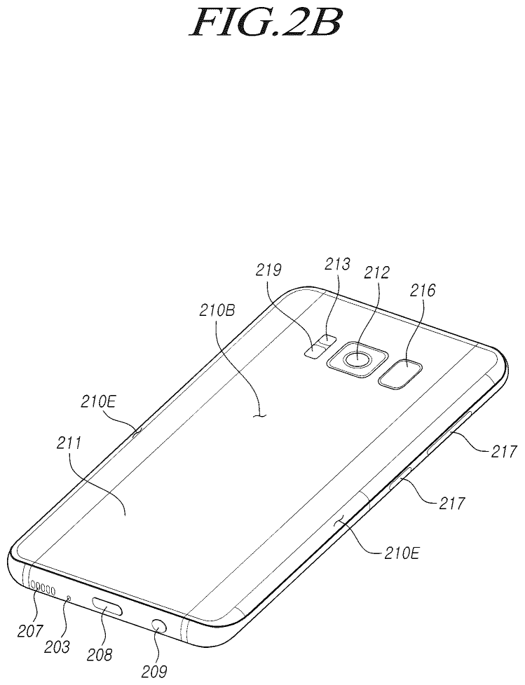

FIG. 2A is a front perspective view illustrating an electronic device according to an embodiment of the disclosure. FIG. 2B is a rear perspective view illustrating the electronic device of FIG. 2A according to an embodiment of the disclosure.

Referring to FIGS. 2A and 2B, according to an embodiment, an electronic device 200 may include a housing 210 including a first surface (or front surface) 210A, a second surface (or rear surface) 210B, and a side surface 210C surrounding a space between the first surface 210A and the second surface 210B. According to another embodiment (not shown), the housing may denote a structure forming part of the first surface 210A, the second surface 210B, and the side surface 210C of FIG. 2B. According to an embodiment, at least part of the first surface 210A may have a substantially transparent front plate 202 (e.g., a glass plate or polymer plate including various coat layers). The second surface 210B may be formed by a rear plate 211 that is substantially opaque. The rear plate 211 may be formed of, e.g., laminated or colored glass, ceramic, polymer, metal (e.g., aluminum, stainless steel (STS), or magnesium), or a combination of at least two thereof. The side surface 210C may be formed by a side bezel structure (or a “side member”) 218 that couples to the front plate 202 and the rear plate 211 and includes a metal and/or polymer. In some embodiments, the rear plate 211 and the side bezel structure 218 may be integrally formed and include the same material (e.g., a metal material such as aluminum).

In the embodiment illustrated, the front plate 202 may include two first areas 210D, which seamlessly and bendingly extend from the first surface 210A to the rear plate 211, on both the long edges of the front plate 202. In the embodiment (refer to FIG. 2B) illustrated, the rear plate 211 may include second areas 210E, which seamlessly and bendingly extend from the second surface 210B to the front plate 202, on both the long edges. According to an embodiment, the front plate 202 (or the rear plate 211) may include only one of the first areas 210D (or the second areas 210E). Alternatively, the first areas 210D or the second areas 210E may partially be excluded. According to an embodiment, in side view of the electronic device 200, the side bezel structure 218 may have a first thickness (or width) for sides that do not have the first areas 210D or the second areas 210E and a second thickness, which is smaller than the first thickness, for sides that have the first areas 210D or the second areas 210E. In an embodiment, the first areas 210D or second areas 210E may be formed to be flat to, together the first surface 210A or second surface 210B, form substantially one flat surface without bending.

According to an embodiment, the electronic device 200 may include at least one or more of a display 201, audio modules 203, 207, and 214, sensor modules 204, 216, and 219, camera modules 205, 212, and 213, key input devices 217, a light emitting device 206, and connector holes 208 and 209. According to an embodiment, the electronic device 200 may exclude at least one (e.g., the key input device 217 or the light emitting device 206) of the components or may add other components.

The display 201 may be exposed through a significant portion of the front plate 202. According to an embodiment, at least a portion of the display 201 may be exposed through the front plate 202 forming the first surface 210A and the first areas 210D of the side surface 210C. According to an embodiment, the edge of the display 201 may be formed to be substantially the same in shape as an adjacent outer edge of the front plate 202. According to another embodiment (not shown), the gap between the outer edge of the display 201 and the outer edge of the front plate 202 may remain substantially even to give a larger area of exposure the display 201.

According to an embodiment (not shown), the screen display area of the display 201 may have a recess or opening in a portion thereof, and at least one or more of the audio module 214, sensor module 204, camera module 205, and light emitting device 206 may be aligned with the recess or opening. According to another embodiment (not shown), at least one or more of the audio module 214, sensor module 204, camera module 205, fingerprint sensor (i.e., sensor module 216), and light emitting device 206 may be included on the rear surface of the screen display area of the display 201. In another embodiment (not shown), the display 201 may be disposed to be coupled with, or adjacent, a touch detecting circuit, a pressure sensor capable of measuring the strength (pressure) of touches, and/or a digitizer for detecting a magnetic field-type stylus pen. According to an embodiment, at least part of the sensor modules 204 and 219 and/or at least part of the key input devices 217 may be disposed in the first areas 210D and/or the second areas 210E.

The audio modules 203, 207, and 214 may include a microphone hole 203 and speaker holes 207 and 214. The microphone hole 203 may have a microphone inside to obtain external sounds. According to an embodiment, there may be a plurality of microphones to be able to detect the direction of a sound. The speaker holes 207 and 214 may include an external speaker hole 207 and a phone receiver hole 214. According to an embodiment, the speaker holes 207 and 214 and the microphone hole 203 may be implemented as a single hole, or speakers may be rested without the speaker holes 207 and 214 (e.g., piezo speakers).

The sensor modules 204, 216, and 219 may generate an electrical signal or data value corresponding to an internal operating state or external environmental state of the electronic device 200. The sensor modules 204, 216, and 219 may include a first sensor module 204 (e.g., a proximity sensor) disposed on the first surface 210A of the housing 210, and/or a second sensor module (not shown) (e.g., a fingerprint sensor), and/or a third sensor module 219 (e.g., a heart-rate monitor (HRM) sensor) disposed on the second surface 210B of the housing 210, and/or a fourth sensor module 216 (e.g., a fingerprint sensor). The fingerprint sensor may be disposed on the second surface 210B as well as on the first surface 210A (e.g., the display 201) of the housing 210. The electronic device 200 may further include sensor modules not shown, e.g., at least one of a gesture sensor, a gyro sensor, an atmospheric pressure sensor, a magnetic sensor, an acceleration sensor, a grip sensor, a color sensor, an infrared (IR) sensor, a biometric sensor, a temperature sensor, a humidity sensor, or an illuminance sensor 204.

The camera modules 205, 212, and 213 may include a first camera device 205 disposed on the first surface 210A of the electronic device 200, and a second camera device 212 and/or a flash 213 disposed on the second surface 210B. The camera devices 205 and 212 may include one or more lenses, an image sensor, and/or an image signal processor. The flash 213 may include, e.g., a light emitting diode (LED) or a xenon lamp. According to an embodiment, two or more lenses (an infrared (IR) camera, a wide-angle lens, and a telephoto lens) and image sensors may be disposed on one surface of the electronic device 200.

The key input device 217 may be disposed on the side surface 210C of the housing 210. According to another embodiment, the electronic device 200 may exclude all or some of the above-mentioned key input devices 217 and the excluded key input devices 217 may be implemented in other forms, e.g., as soft keys, on the display 201. According to an embodiment, the key input device may include the sensor module 216 disposed on the second surface 210B of the housing 210.

The light emitting device 206 may be disposed on, e.g., the first surface 210A of the housing 210. The light emitting device 206 may provide, e.g., information about the state of the electronic device 200 in the form of light. According to an embodiment, the light emitting device 206 may provide a light source that interacts with, e.g., the camera module 205. The light emitting device 206 may include, e.g., a light emitting diode (LED), an infrared (IR) LED, or a xenon lamp.

The connector holes 208 and 209 may include a first connector hole 208 for receiving a connector (e.g., a universal serial bus (USB) connector) for transmitting or receiving power and/or data to/from an external electronic device and/or a second connector hole 209 (e.g., an earphone jack) for receiving a connector for transmitting or receiving audio signals to/from the external electronic device.

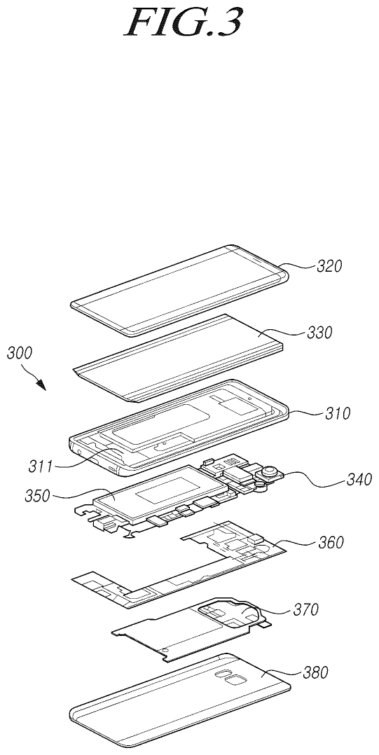

FIG. 3 is an exploded perspective view illustrating an electronic device according to an embodiment of the disclosure.

Referring to FIG. 3, an electronic device 300 may include a side bezel structure 310, a first supporting member 311 (e.g., a bracket), a front plate 320, a display 330, a printed circuit board (PCB) 340, a battery 350, a second supporting member 360 (e.g., a rear case), an antenna 370, and a rear plate 380. According to an embodiment, the electronic device 300 may exclude at least one (e.g., the first supporting member 311 or the second supporting member 360) of the components or may add other components. At least one of the components of the electronic device 300 may be the same or similar to at least one of the components of the electronic device 101 of FIG. 1 or 2 and no duplicate description is made below.

The first supporting member 311 may be disposed inside the electronic device 300 to be connected with the side bezel structure 310 or integrated with the side bezel structure 310. The first supporting member 311 may be formed of, e.g., a metal and/or non-metallic material (e.g., polymer). The display 330 may be joined onto one surface of the first supporting member 311, and the printed circuit board 340 may be joined onto the opposite surface of the first supporting member 311. A processor, memory, and/or interface may be mounted on the printed circuit board 340. The processor may include one or more of, e.g., a central processing unit, an application processor, a graphics processing device, an image signal processor, a sensor hub processor, or a communication processor.

The memory may include, e.g., a volatile or non-volatile memory.

The interface may include, e.g., a high definition multimedia interface (HDMI), a universal serial bus (USB) interface, a secure digital (SD) card interface, and/or an audio interface. The interface may electrically or physically connect, e.g., the electronic device 300 with an external electronic device and may include a USB connector, an SD card/multimedia card (MMC) connector, or an audio connector.

The battery 350 may be a device for supplying power to at least one component of the electronic device 300. The battery 350 may include, e.g., a primary cell which is not rechargeable, a secondary cell which is rechargeable, or a fuel cell. At least a portion of the battery 350 may be disposed on substantially the same plane as the printed circuit board 340. The battery 350 may be integrally or detachably disposed inside the electronic device 300.

The antenna 370 may be disposed between the rear plate 380 and the battery 350. The antenna 370 may include, e.g., a near-field communication (NFC) antenna, a wireless charging antenna, and/or a magnetic secure transmission (MST) antenna. The antenna 370 may perform short-range communication with, e.g., an external device or may wirelessly transmit or receive power necessary for charging. According to an embodiment, an antenna structure may be formed by a portion or combination of the side bezel structure 310 and/or the first supporting member 311.

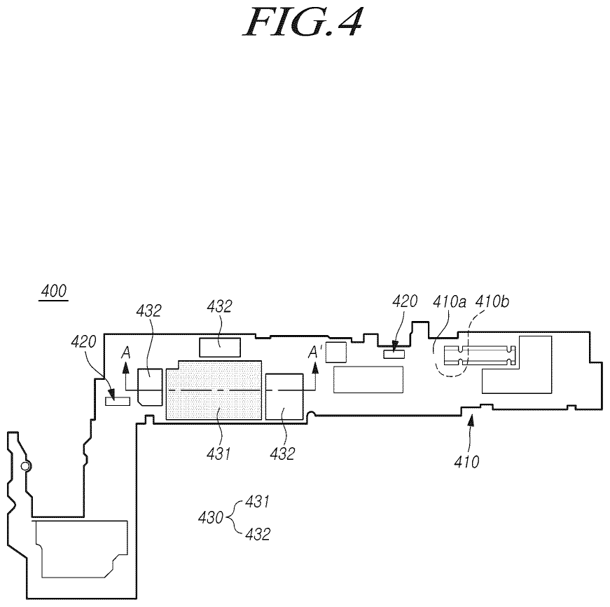

FIG. 4 is a plan view illustrating a printed circuit board assembly according to an embodiment of the disclosure.

A printed circuit board assembly 400 illustrated in FIG. 4 may be received within an electronic device (e.g., the electronic device 200 of FIG. 2A) illustrated in FIGS. 2A, 2B, and 3. The printed circuit board assembly 400 illustrated in FIG. 4 may replace or be included in a PCB (e.g., the printed circuit board 340 of FIG. 3) of an electronic device (e.g., the electronic device 300 of FIG. 3) illustrated in FIG. 3.

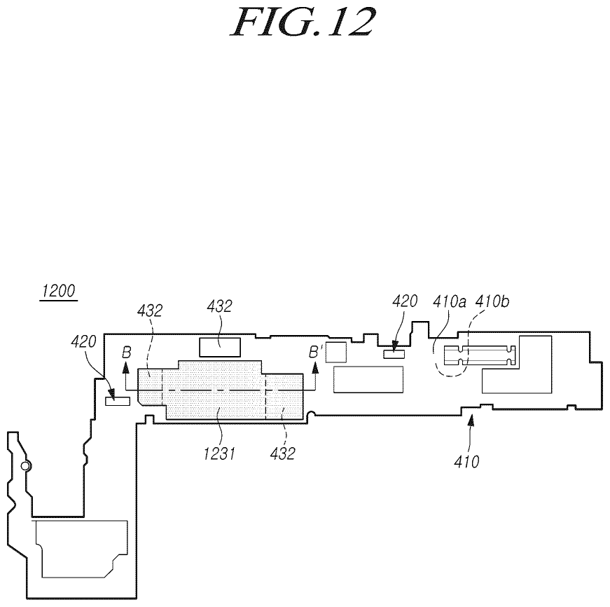

The embodiment of FIG. 4 may be selectively combined with the embodiments of FIGS. 12 to 16.

Referring to FIG. 4, a printed circuit board assembly 400 may include at least one of a PCB 410, a plurality of electronic components 420, a first shielding member 431, or a second shielding member 432. The first shielding member 431 or the second shielding member 432 may be referred to as, e.g., a shield can. For example, a support portion 4311 of the first shielding member 431 may be referred to as a shield can.

The printed circuit board assembly 400 may be, e.g., a module such as a solid state drive (SSD) module, a memory module, a computer system module, or a mobile system module, but is not limited thereto. The printed circuit board assembly 400 may be a semiconductor substrate. In the following description, the printed circuit board assembly 400 will be specifically described as a semiconductor substrate, but the proposed structure or manufacturing method thereof may not be specifically applied only to the semiconductor substrate, but may be applied to all printed circuit board assemblies made by mounting electronic components by soldering.

The PCB 410 may include a first surface 410a or a second surface 410b. The first surface 410a and the second surface 410b may be surfaces facing opposite directions. For example, the first surface 410a may be a surface facing a display (e.g., the display 330 of FIG. 3) in case that the PCB 410 is disposed in an electronic device (e.g., the electronic device 300 of FIG. 3). The PCB 410 may be configured such that, e.g., at least one electronic component is mounted by soldering on at least one of the first surface 410a and the second surface 410b.

Various types of substrates well known in the art (e.g., a ceramic substrate, a printed circuit board, a flexible substrate, etc.) may be used for the PCB 410. Although not illustrated, electrically connected line patterns may be formed on at least one of the first surface 410a and the second surface 410b of the PCB 410.

The PCB 410 may be divided into a single layer PCB having circuit lines formed on only one surface and a double layer PCB having circuit lines formed on two opposite surfaces. In the case of a PCB 410 for a double-sided PCB, upper and lower circuit lines may be electrically connected through a conductive via penetrating the body.

According to an example, the plurality of electronic components 420 may be mounted on the PCB 410. The plurality of electronic components 420 may be mounted on at least one of the first surface 410a or the second surface 410b of the PCB 410.

According to an example, a portion of the plurality of electronic components 420 may be shielded by a shielding member 430. The shielding member 430 may be disposed to protect the plurality of electronic components 420 from external impacts. The shielding member 430 may be disposed to surround at least one of the plurality of electronic components 420. For example, the shielding member 430 may be disposed to surround a portion of the plurality of electronic components 420 mounted on the first surface 410a. For example, the shielding member 430 may be disposed to surround a portion of the plurality of electronic components 420 mounted on the second surface 410b.

According to an example, the shielding member 430 may include a first shielding member 431 and a second shielding member 432. According to an example, the plurality of electronic components 420 may be shielded from the outside by the first shielding member 431 or the second shielding member 432. For example, the first shielding member 431 and the second shielding member 432 may be disposed on the first surface 410a of the PCB 410.

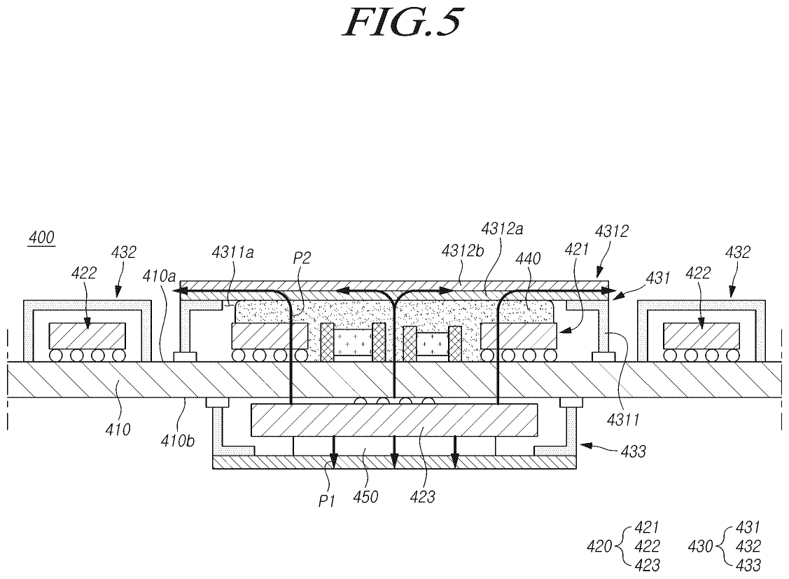

The first shielding member 431 may be positioned at a location corresponding to a third electronic component (e.g., the third electronic component 423 of FIG. 5 or a main heat generating element) mounted on the second surface 410b to be described below. The first shielding member 431 may be disposed such that at least a partial area overlaps the third electronic component 423 mounted on the second surface 410b to be described below.

The second shielding member 432 may be disposed around the first shielding member 431. The second shielding member 432 may be disposed on a side of the first shielding member 431. The second shielding member 432 may be positioned within a predetermined distance from the first shielding member 431. A plurality of second shielding members 432 may be provided around the first shielding member 431.

FIG. 5 is a cross-sectional view illustrating a printed circuit board assembly according to an embodiment of the disclosure.

FIG. 5 may be a cross-sectional view taken along line A-A′ in the printed circuit board assembly 400 of FIG. 4. The drawing illustrated in FIG. 5 is schematically illustrated for convenience of description, and the scope of rights of the disclosure is not limited to the illustrated form.

The embodiment of FIG. 5 may be selectively combined with the embodiments of FIGS. 12 to 16.

Referring to FIG. 5, a printed circuit board assembly 400 may include at least one of a PCB 410, a shielding member 430, a plurality of electronic components 420, a first heat transfer member 440, or a second heat transfer member 450.

According to an example, the shielding member 430 may include a first shielding member 431, a second shielding member 432, and a third shielding member 433. The first shielding member 431 and the second shielding member 432 may be disposed on the first surface 410a of the PCB 410. The third shielding member 433 may be disposed on the second surface 410b of the PCB 410. The first shielding member 431 and the third shielding member 433 may be disposed in areas corresponding to each other.

According to an example, the first shielding member 431 may include a support portion 4311 and a cover portion 4312. The support portion 4311 and the cover portion 4312 may be configured to protect the plurality of first electronic components 421 disposed within the first shielding member 431 from external impacts and to efficiently dissipate heat.

According to an example, the cover portion 4312 may be configured to be thermally compressible. The cover portion 4312 may have a non-restorable property that does not return to its original shape after thermal deformation. In case that heat above a predetermined temperature is applied to the cover portion 4312, the cover portion 4312 may be plastically deformed. The cover portion 4312 may simultaneously have shielding and heat dissipation functions.

According to an example, the cover portion 4312 may include a heat transfer layer 4312b. The heat transfer layer 4312b may, e.g., form an upper surface of the cover portion 4312. The heat transfer layer 4312b may have, e.g., a thermal conductivity of up to 1400 W/mK, but the disclosure is not limited thereto. For example, the heat transfer layer 4312b may be a graphite sheet. However, the disclosure is not limited thereto.

According to an example, the heat transfer layer 4312b may disperse heat transferred from the first heat transfer member 440 in a horizontal direction. By redistributing heat transferred vertically from the main heat generating element to the first heat transfer member 440 in a horizontal direction, heat dissipation performance of the printed circuit board assembly 400 may be enhanced.

According to an example, the cover portion 4312 may include a shielding layer 4312a. The shielding layer 4312a may be disposed below the heat transfer layer 4312b. Unlike illustrated, the shielding layer 4312a may be disposed above the heat transfer layer 4312b. The shielding layer 4312a may have, e.g., a thermal conductivity of 300 to 400 W/mK, but the disclosure is not limited thereto. The shielding layer 4312a may have, e.g., a relatively smaller thermal conductivity compared to the heat transfer layer 4312b. The shielding layer 4312a may, e.g., include copper. However, the disclosure is not limited thereto. According to an example, the heat transfer layer 4312b and the shielding layer 4312a may be laminated together.

Unlike illustrated, the cover portion 4312 may not be in a state in which the heat transfer layer 4312b and the shielding layer 4312a are laminated. Unlike illustrated, the cover portion 4312 may be configured with the heat transfer layer 4312b omitted. In this case, since the shielding layer 4312a has high thermal conductivity properties, the shielding layer 4312a may play a role in dispersing heat transferred from the first heat transfer member 440.

Unlike illustrated, the cover portion 4312 may be configured with at least a portion of the heat transfer layer 4312b or the shielding layer 4312a omitted in some areas while the heat transfer layer 4312b and the shielding layer 4312a are laminated.

According to an example, the support portion 4311 may be provided to support the cover portion 4312. The support portion 4311 may form a side portion or side surface of the first shielding member 431. The support portion 4311 may be disposed between the PCB 410 and the cover portion 4312. The support portion 4311 may include an opening 4311a having an open top. The cover portion 4312 may be disposed to cover the opening 4311a. The support portion 4311 may be configured to shield electromagnetic waves generated from the plurality of first electronic components 421.

According to an example, the second shielding member 432 may be disposed around the first shielding member 431. The second shielding member 432 may be disposed adjacent to the first shielding member 431.

According to an example, the third shielding member 433 may be disposed on an opposite side of the first shielding member 431.

According to an example, the plurality of electronic components 420 may include a plurality of first electronic components 421, a plurality of second electronic components 422, and a third electronic component 423. The plurality of first electronic components 421 may be mounted on the first surface 410a of the PCB 410. The plurality of first electronic components 421 may be positioned inside the first shielding member 431. The plurality of second electronic components 422 may be mounted on the first surface 410a of the PCB 410. The plurality of second electronic components 422 may be positioned inside the second shielding member 432. The third electronic component 423 may be mounted on the second surface 410b of the PCB 410. The third electronic component 423 may be positioned inside the third shielding member 433.

According to an example, each of the plurality of first electronic components 421 may have different heights and sizes. According to an example, the third electronic component 423 may include a main heat generating element. The main heat generating element may be mounted on the second surface 410b of the PCB 410. The main heat generating element may include, e.g., at least one of an application processor (AP), a central processing unit (CPU), a graphics processing unit (GPU), a power amplifying module (PAM), or memory. However, without limitations thereto, the main heat generating element may include elements that need to operate at high clocks for high-performance operation.

Since steps are formed due to different heights of each of the plurality of first electronic components 421, in case that a heat transfer member having a fixed shape or elasticity is disposed on the plurality of first electronic components 421, the heat transfer member may not fill the stepped spaces. In case that a liquid heat transfer member is applied around the plurality of first electronic components 421, surface tension and capillary forces act simultaneously, making it difficult for the liquid heat transfer member to penetrate into spaces between the plurality of first electronic components 421. Further, in case of using a liquid heat transfer member, leakage or backflow problems during heat transfer member injection may occur. In the disclosure, using a thermally compressible heat transfer member, the first heat transfer member 440 is provided not only on an upper side of the plurality of first electronic components 421 but also on the sides of each of the plurality of first electronic components 421, thereby widening a contact area between the plurality of first electronic components 421 and the first heat transfer member 440. By maximizing the contact area between the plurality of first electronic components 421 and the first heat transfer member 440, thermal resistance may be decreased. As a result, a portion of heat generated from the main heat generating element may be efficiently released to the outside through the PCB 410 and the first heat transfer member 440.

According to an example, the first heat transfer member 440 may be received within the first shielding member 431. A portion of the first heat transfer member 440 may be disposed in a space formed between the plurality of first electronic components 421. The first heat transfer member 440 may be provided to tightly contact surfaces of the plurality of first electronic components 421.

According to an example, the first heat transfer member 440 may be configured to be thermally deformable. For example, the first heat transfer member 440 may be configured to be deformable in case that it reaches a predetermined temperature or higher.

According to an example, the first heat transfer member 440 may be disposed at a portion corresponding to the third electronic component 423 (or main heat generating element). For example, the first heat transfer member 440 may be disposed on an opposite side of the third electronic component 423 (or main heat generating element) with the PCB 410 therebetween.

According to an example, the first heat transfer member 440 may include a heat dissipation material having high thermal conductivity. The heat dissipation material having high thermal conductivity may include at least one of aluminum oxide (Al₂O₃), aluminum nitride (AlN), boron nitride (BN), silicon carbide (SiC), magnesium oxide (MgO), zinc oxide (ZnO), carbon fiber, or graphene. However, the disclosure is not limited thereto. For example, the heat dissipation material having high thermal conductivity may have a weight ratio of 86% to 94% in the first heat transfer member 440.

According to an example, the first heat transfer member 440 may include a rubber material. By including a rubber material in the first heat transfer member 440, the first heat transfer member 440 may have compression performance. Further, in case that the first heat transfer member 440 is compressed, the first heat transfer member 440 may be brought into tight contact with surfaces of the plurality of first electronic components 421 by the rubber material included in the first heat transfer member 440. For example, the rubber material may have a weight ratio of 6.75% to 8.25% in the first heat transfer member 440.

According to an example, the first heat transfer member 440 may include a phase change material (PCM). The phase change material may enable the first heat transfer member 440 to change shape by heat. For example, the phase change material may include a paraffin-based material, but the disclosure is not limited thereto. For example, the phase change material may have a weight ratio of 6.75% to 8.25% in the first heat transfer member 440.

According to an example, the first heat transfer member 440 may be configured to maintain a solid form at room temperature. The first heat transfer member 440 may have, e.g., a glass transition temperature of 40 degrees Celsius or higher. The first heat transfer member 440 may have, e.g., a weight ratio of 85:7.5:7.5 for heat dissipation material with high thermal conductivity, rubber material, and phase change material, but the disclosure is not limited thereto. For example, it may be configured to be changeable within a 10% range for each material.

Although the first heat transfer member 440 is illustrated as being received within the first shielding member 431, thermally compressible first heat transfer member 440 may also be received within other shielding members.

According to an example, the second heat transfer member 450 may be received in the third shielding member 433. The second heat transfer member 450 may be disposed between the third electronic component 423 (or main heat generating element) and the third shielding member 433. The second heat transfer member 450 may be disposed to transfer heat generated from the third electronic component 423 (or main heat generating element) to the outside.

According to an example, heat generated from the main heat generating element of the third electronic component 423 may be dissipated through a first heat dissipation path P1 and a second heat dissipation path P2. The first heat dissipation path P1 may include, e.g., a path where heat generated from the main heat generating element sequentially passes through the second heat transfer member 450 and the third shielding member 433 to be dissipated to the outside.

According to an example, the second heat dissipation path P2 may include a path where heat generated from the main heat generating element sequentially passes through the PCB 410, the first heat transfer member 440, and the first shielding member 431 to be dissipated to the outside. The second heat dissipation path P2 may include, e.g., a path where heat is transferred from the main heat generating element to the PCB 410 and the first heat transfer member 440, and heat from the first heat transfer member 440 is dissipated horizontally through the cover portion 4312 of the first shielding member 431. Heat transferred from the main heat generating element may be dissipated horizontally by, e.g., the heat transfer layer 4312b of the cover portion 4312. Here, the horizontal direction may refer to a planar direction of the cover portion 4312. In the disclosure, by additionally configuring the second heat dissipation path P2 as well as the first heat dissipation path P1, heat dissipation performance of the main heat generating element may be enhanced.

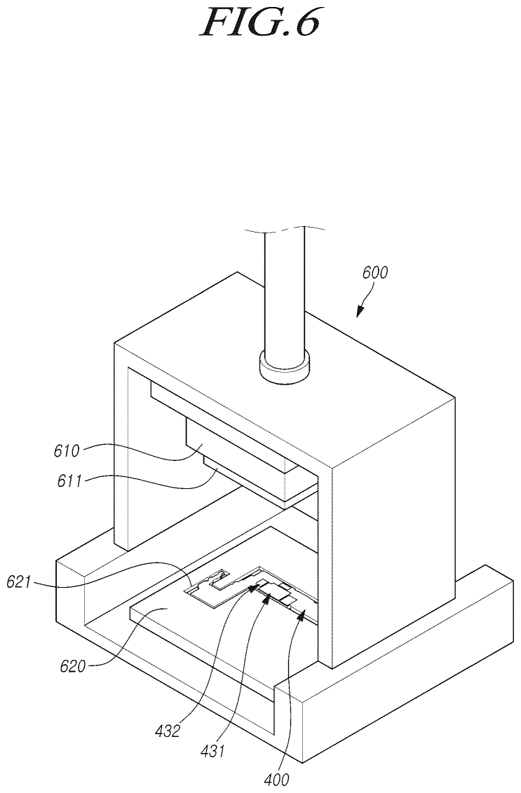

FIG. 6 is a perspective view illustrating a thermal compression device according to an embodiment of the disclosure.

Referring to FIG. 6, a thermal compression device 600 may include an upper jig 610 and a lower jig 620.

According to an example, the upper jig 610 may be configured to be vertically movable. The upper jig 610 may include a heating block 611. The heating block 611 may have, e.g., a temperature of 130 degrees or higher.

According to an example, the lower jig 620 may include a seating groove 621. A printed circuit board assembly 400 may be seated in the seating groove 621. The printed circuit board assembly 400 may be seated in the seating groove 621 with the first shielding member 431 facing upward. The seating groove 621 should be formed at an appropriate depth to prevent damage to the third electronic component (e.g., the third electronic component 423 of FIG. 5) (or main heat generating element) mounted on the second surface (e.g., the second surface 410b of FIG. 5) opposite to the first shielding member 431. For example, the seating groove 621 may be formed with an intaglio of 4.5 to 5.1 T. For example, the seating groove 621 may have an intaglio of 4.8 T applied.

According to an example, an additional intaglio may be formed at a portion corresponding to or overlapping the first shielding member 431 in the seating groove 621. For example, an additional intaglio of 0.25 to 0.45T may be formed at a portion corresponding to the first shielding member 431 in the seating groove 621.

According to an example, the first shielding member 431 of the printed circuit board assembly 400 may be thermally compressed by thermal compression device 600. As the upper jig 610 moves toward the lower jig 620, the first shielding member 431 of the printed circuit board assembly 400 seated in the seating groove 621 may be thermally compressed. In a process in which the upper jig 610 compresses the printed circuit board assembly 400, the heating block 611 may contact the first shielding member 431. The first shielding member 431 and the first heat transfer member (e.g., the first heat transfer member 440 of FIG. 5) received within the first shielding member may be heated by the heating block 611.

In case of pressing the printed circuit board assembly 400 using the upper jig 610 and the lower jig 620, to prevent damage to a portion of the printed circuit board assembly 400 being pressed, thermal compression device 600 may include an elastic pad. The elastic pad may be, e.g., a silicone pad or a rubber pad.

Although not illustrated, in case that the upper jig 610 presses the cover portion 4312 of the first shielding member 431, a release paper may be provided above the cover portion 4312 to prevent damage to the cover portion 4312. The release paper may prevent damage to the heat transfer layer 4312b positioned over the cover portion 4312.

In case that the upper jig 610 moves downward to press the first shielding member 431, the first shielding member 431 should be pressed with appropriate pressure so that the third electronic component (e.g., the third electronic component 423 of FIG. 5) disposed on the opposite side is not damaged. For example, the upper jig 610 may press the first shielding member 431 with a pressure of about 0.8 bar or more.

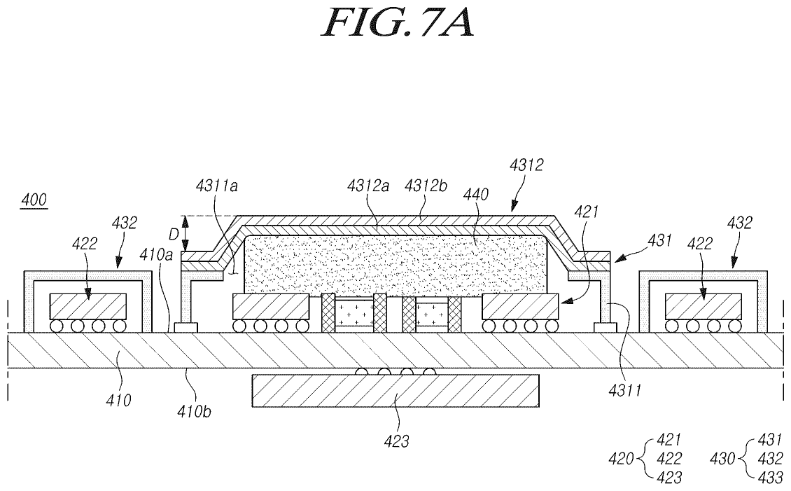

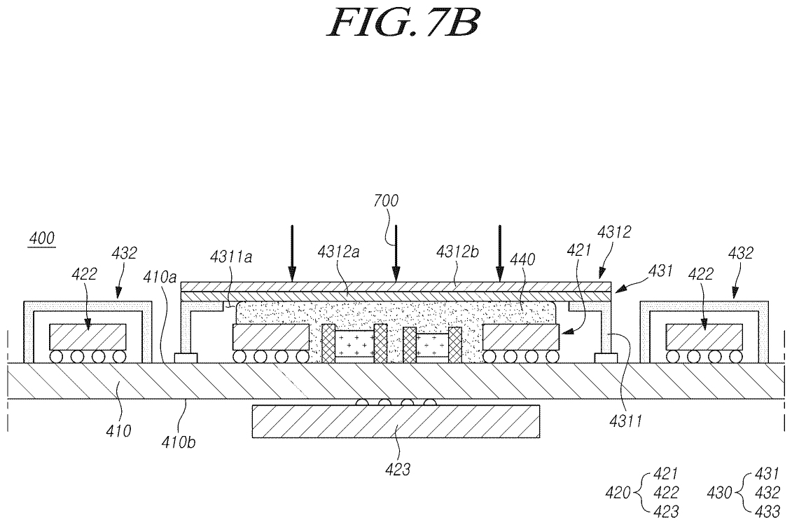

FIGS. 7A and 7B are cross-sectional views illustrating a process of thermally compressing a first shielding member and a first heat transfer member according to various embodiments of the disclosure.

The configuration of the printed circuit board assembly 400 illustrated in FIGS. 7A and 7B may be substantially identical or similar to the configuration of the printed circuit board assembly 400 illustrated in FIG. 5. For configurations illustrated in FIGS. 7A and 7B that are substantially identical or similar to configurations illustrated in FIG. 5, the same reference numbers are used.

The embodiments of FIGS. 7A and 7B may be selectively combined with the embodiments of FIGS. 12 to 16.

FIG. 7A is a cross-sectional view illustrating a state before the printed circuit board assembly 400 is thermally compressed.

Before the first heat transfer member 440 is thermally compressed, the first heat transfer member 440 may be disposed on the plurality of first electronic components 421. The first heat transfer member 440 may be disposed on the plurality of first electronic components 421 in, e.g., about a block shape. The first shielding member 431 may be disposed on the first heat transfer member 440. Since the first heat transfer member 440 is in a state before being thermally compressed, a portion of the cover portion 4312 of the first shielding member 431 may protrude upward. For example, a portion of the cover portion 4312 may be disposed on the first heat transfer member 440 protruding upward by an amount D illustrated in FIG. 7A. The degree of protrusion of the cover portion 4312 may be somewhat exaggerated for convenience of description.

FIG. 7B is a cross-sectional view illustrating a state after the printed circuit board assembly 400 is thermally compressed.

The first shielding member 431 and the first heat transfer member 440 may be thermally compressed by thermal compression device 600. For example, the first shielding member 431 and the first heat transfer member 440 may be compressed by a length D protruding upward from the first shielding member 431. The first shielding member 431 and the first heat transfer member 440 may be thermally compressed by being pressed in a downward direction 700.

In case that the first heat transfer member 440 is thermally compressed in the downward direction 700, a portion may permeate into spaces between the plurality of first electronic components 421 as illustrated in FIG. 7B.

After thermal compression, the cover portion 4312 and an upper surface of the electronic component with the highest height among the plurality of first electronic components 421 may be spaced apart from each other. For example, to increase heat dissipation performance, a distance between the cover portion 4312 and the upper surface of the electronic component with the highest height among the plurality of first electronic components 421 may be 50 micrometers or more.

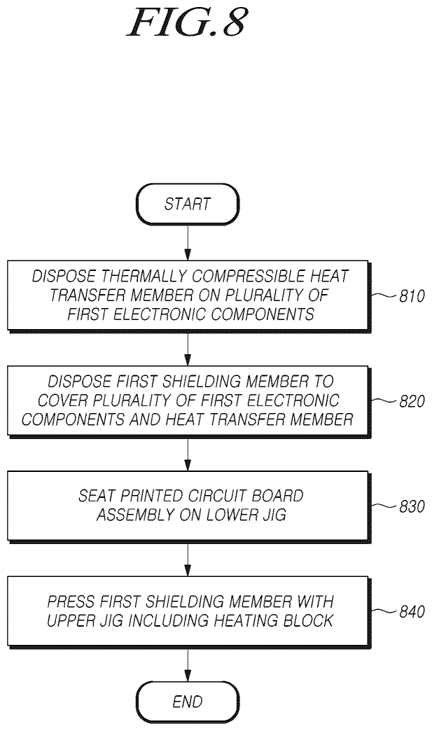

FIG. 8 is a flowchart illustrating a manufacturing method of a printed circuit board assembly according to an embodiment of the disclosure.

The flowchart of FIG. 8 is a flowchart illustrating a portion of a process of manufacturing the printed circuit board assembly 400 of FIG. 5. Hereinafter, description is made based on the configuration of the printed circuit board assembly 400 of FIG. 5.

According to an example, a manufacturing method for the printed circuit board assembly 400 may include a process 810 of disposing a thermally compressible first heat transfer member 440 on the plurality of first electronic components 421. The first heat transfer member 440 may have about a block shape. Before the first heat transfer member 440 is compressed, it may be disposed to overlap on the plurality of first electronic components 421.

According to an example, the manufacturing method for the printed circuit board assembly 400 may include a process 820 of disposing the first shielding member 431 to cover the plurality of first electronic components 421 and the first heat transfer member 440. The printed circuit board assembly 400 after completing process 820 may correspond to the shape illustrated in FIG. 7A.

According to an example, processes 810 and 820 may be performed as a single process. According to an example, after attaching the first heat transfer member 440 to the first shielding member 431, the first shielding member 431 with the first heat transfer member 440 attached may be disposed on the plurality of first electronic components 421.

According to an example, the manufacturing method for the printed circuit board assembly 400 may include a process 830 of seating the printed circuit board assembly 400 on a lower jig (e.g., the lower jig 620 of FIG. 6). The printed circuit board assembly 400 may be seated on the lower jig 620 with the first shielding member 431 facing upward. The printed circuit board assembly 400 may be seated in the seating groove 621 of the lower jig 620.

According to an example, the manufacturing method for the printed circuit board assembly 400 may include a process 840 where an upper jig (e.g., the upper jig 610 of FIG. 6) including a heating block (e.g., the heating block 611 of FIG. 6) presses the first shielding member 431. The upper jig 610 may press the cover portion 4312 of the first shielding member 431. In case that the upper jig 610 presses the printed circuit board assembly 400, appropriate pressure should be applied so that the third electronic component (e.g., the third electronic component 423 of FIG. 5) disposed on the opposite side is not damaged. For example, the printed circuit board assembly 400 may be pressed with a pressure of 0.7 to 0.9 bar. The printed circuit board assembly 400 after completing process 840 may correspond to the shape illustrated in FIG. 7B.

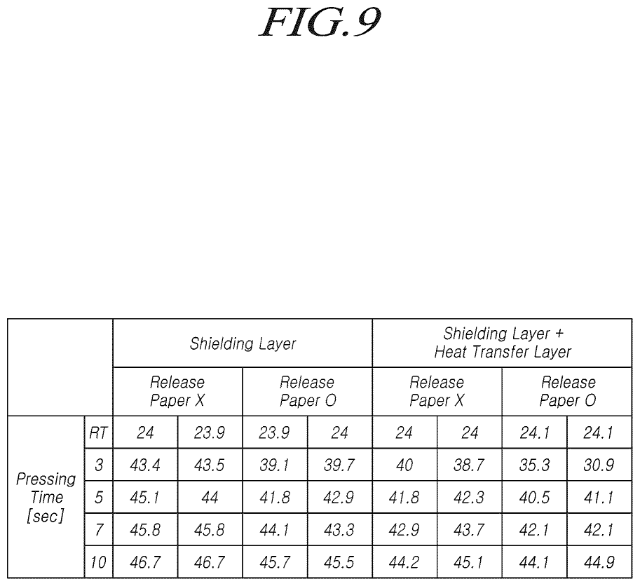

FIG. 9 is an experimental example illustrating temperature changes of a first heat transfer member over time in case of thermally compressing a first shielding member and a first heat transfer member according to an embodiment of the disclosure.

The table illustrated in FIG. 9 is an experimental example, and the experimental results illustrated do not limit the scope of rights of the disclosure. The experimental example of FIG. 9 is experimental data based on a case where the temperature of the heating block (e.g., the heating block 611 of FIG. 6) is 130 degrees. The temperature of the heating block 611 may be 125 degrees Celsius to 135 degrees Celsius.

Referring to FIG. 9, temperature changes over time are displayed as the upper jig (e.g., the upper jig 610 of FIG. 6) including the heating block 611 presses the first shielding member 431. The temperature values displayed in FIG. 9 may represent temperature values inside the first shielding member 431. The table of FIG. 9 displays temperature change values over time inside the first shielding member 431 for each case where the cover portion 4312 is composed of laminated heat transfer layer 4312b and shielding layer 4312a, and where it is composed only of shielding layer 4312a. Further, temperature change values over time inside the first shielding member 431 according to the presence or absence of release paper are displayed.

The temperature inside the first shielding member 431 should exceed the glass transition temperature of the first heat transfer member 440 for the first heat transfer member 440 to be deformed by thermal compression. For example, in case that the glass transition temperature of the first heat transfer member 440 is 40 degrees Celsius, based on experimental values, it may be necessary to press for 5 seconds or more regardless of the material of the cover portion 4312 or the presence of release paper. Here, the process of pressing for 5 seconds or more may be performed in process 840 of FIG. 8.

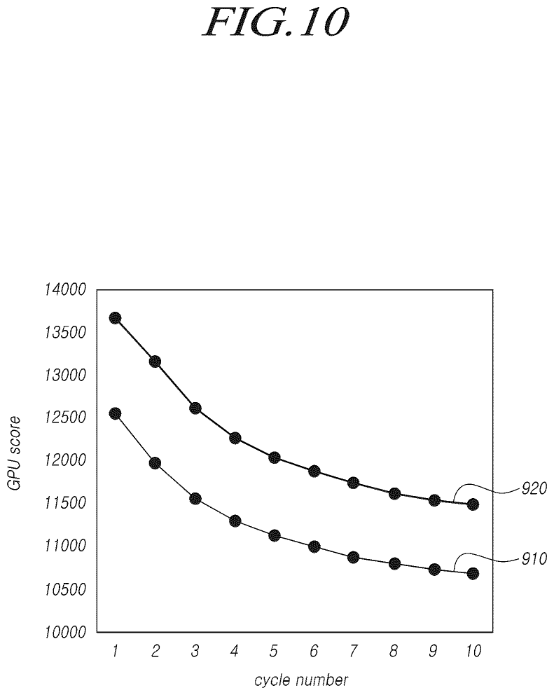

FIG. 10 is a graph for describing enhanced operational performance of a main heat generating element mounted on a printed circuit board assembly according to an embodiment of the disclosure.

The graph of FIG. 10 illustrates performance scores according to cycle numbers of an application processor (AP), which is a component of the third electronic component (e.g., the third electronic component 423 of FIG. 5) or main heat generating element.

Referring to FIG. 10, performance 910 according to cycle numbers of a printed circuit board assembly without the first heat transfer member 440 and performance 920 according to cycle numbers of a printed circuit board assembly (e.g., the printed circuit board assembly 400 of FIG. 5) provided with the first heat transfer member (e.g., the first heat transfer member 440 of FIG. 5) are displayed. Looking at the graph, by providing the first heat transfer member 440 configured to be thermally compressible within the shielding member (e.g., the shielding member 430 of FIG. 4) positioned on the opposite side of the main heat generating element, heat dissipation performance is enhanced and as a result, operational performance may be enhanced by about 10%.

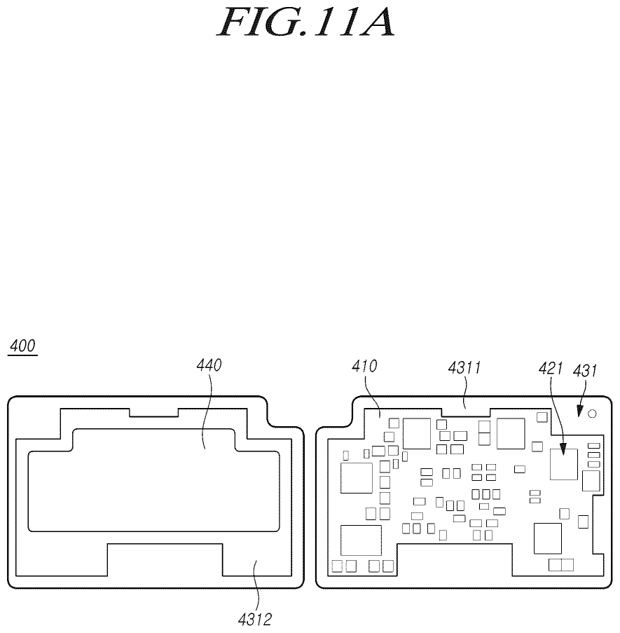

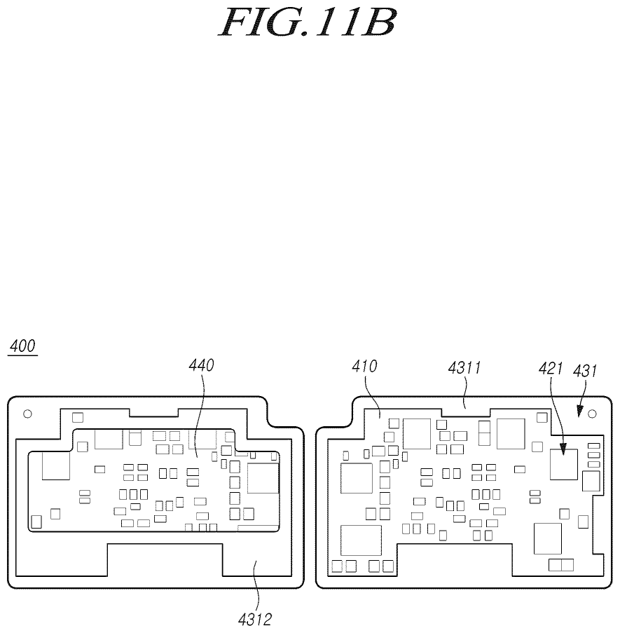

FIGS. 11A and 11B are views illustrating shape changes in case that a first heat transfer member is thermally compressed according to various embodiments of the disclosure.

The printed circuit board assembly 400 illustrated in FIGS. 11A and 11B may be substantially identical or similar to the printed circuit board assembly 400 of FIG. 4. For configurations illustrated in FIGS. 11A and 11B that are substantially identical or similar to configurations illustrated in FIG. 4, the same reference numbers are used.

FIGS. 11A and 11B show a state in which the cover portion 4312 of the first shielding member 431 and the first heat transfer member 440 are separated from the printed circuit board assembly 400. In FIGS. 11A and 11B, the left configuration is a drawing illustrating a state in which the first heat transfer member 440 is attached to the back surface of the cover portion 4312, and the right configuration is a plan view viewed from above after separating the cover portion 4312 and the first heat transfer member 440 from the printed circuit board assembly 400.

FIG. 11A illustrates a state before the first heat transfer member 440 is thermally compressed. FIG. 11A may correspond to the state illustrated in FIG. 7A. FIG. 11B illustrates a state after the first heat transfer member 440 is thermally compressed. FIG. 11B may correspond to the state illustrated in FIG. 7B.

The embodiments of FIGS. 11A and 11B may be selectively combined with the embodiments of FIGS. 12 to 16.

According to an example, after being thermally compressed, the first heat transfer member 440 may have a shape with grooves carved according to the shape of the plurality of first electronic components 421 as illustrated in FIG. 11B. By receiving the plurality of first electronic components 421 in each groove formed in the first heat transfer member 440, a contact area where the plurality of first electronic components 421 and the first heat transfer member 440 contact may be maximized.

FIG. 12 is a plan view illustrating a printed circuit board assembly according to an embodiment of the disclosure.

A printed circuit board assembly 1200 illustrated in FIG. 12 may be received within an electronic device (e.g., the electronic device 200 of FIG. 2A) illustrated in FIGS. 2A, 2B, and 3. The printed circuit board assembly 1200 illustrated in FIG. 12 may replace or be included in a PCB (e.g., the printed circuit board 340 of FIG. 3) of an electronic device (e.g., the electronic device 300 of FIG. 3) illustrated in FIG. 3.

For configurations illustrated in FIG. 12 that are substantially identical or similar to configurations of the printed circuit board assembly 400 illustrated in FIG. 4, the same reference numbers are used.

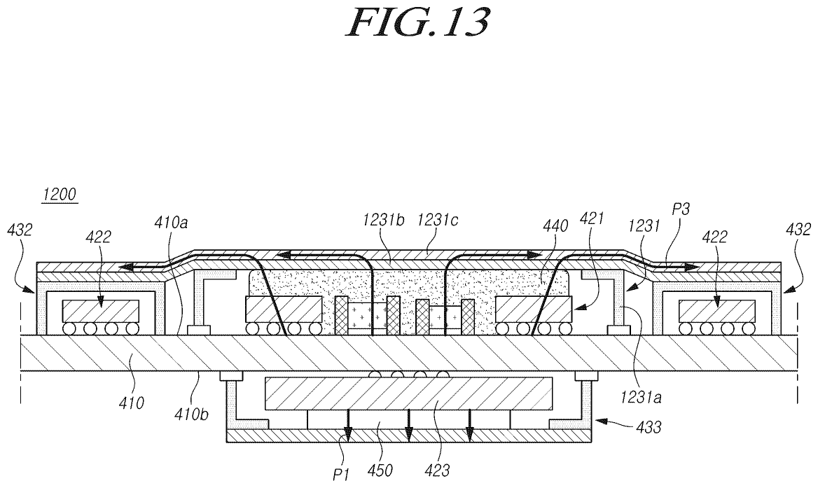

The embodiment of FIG. 12 may be selectively combined with the embodiment of FIGS. 4 to 6, 7A, 7B, 8 to 10, 11A, and 11B. The embodiment of FIG. 12 may be selectively combined with the embodiments of FIGS. 13 to 16.

Referring to FIG. 12, a printed circuit board assembly 1200 may include a first shielding member 1231. The first shielding member 1231 may be positioned at a location corresponding to a third electronic component (e.g., the third electronic component 423 of FIG. 13 or a main heat generating element) mounted on the second surface 410b to be described below. The first shielding member 1231 may be disposed such that at least a partial area overlaps the third electronic component 423 mounted on the second surface 410b to be described below.

According to an example, an upper surface of the first shielding member 1231 may be configured to cover at least one second shielding member 432 among adjacent plurality of second shielding members 432. By extending the area of the upper surface of the first shielding member 1231, a heat dissipation path of the first shielding member 1231 may be widened.

FIG. 13 is a cross-sectional view illustrating a printed circuit board assembly according to an embodiment of the disclosure.

FIG. 13 may be a cross-sectional view taken along line B-B′ in the printed circuit board assembly 1200 of FIG. 12. The drawing illustrated in FIG. 13 is schematically illustrated for convenience of description, and the scope of rights of the disclosure is not limited to the illustrated form.

For configurations illustrated in FIG. 13 that are substantially identical or similar to configurations of the printed circuit board assembly 400 illustrated in FIG. 5, the same reference numbers are used.

Referring to FIG. 13, a printed circuit board assembly 1200 may include a first shielding member 1231.

According to an example, the first shielding member 1231 may include a support portion 1231a and cover portions 1231b, 1231c. The support portion 1231a and the cover portions 1231b, 1231c may be configured to protect the plurality of first electronic components 421 disposed within the first shielding member 1231 from external impacts and to efficiently dissipate heat.

According to an example, the cover portions 1231b, 1231c may be configured to be thermally compressible. The cover portions 1231b, 1231c may have a non-restorable property that does not return to its original shape after thermal deformation. In case that heat above a predetermined temperature is applied to the cover portions 1231b, 1231c, the cover portions 1231b, 1231c may be plastically deformed. The cover portions 1231b, 1231c may simultaneously have shielding and heat dissipation functions.

According to an example, the cover portions 1231b, 1231c may include a heat transfer layer 1231c. The heat transfer layer 1231c may, e.g., form an upper surface of the cover portions 1231b, 1231c. The heat transfer layer 1231c may have, e.g., a thermal conductivity of up to 1400 W/mK, but the disclosure is not limited thereto. For example, the heat transfer layer 1231c may be a graphite sheet. However, the disclosure is not limited thereto.

According to an example, the heat transfer layer 1231c may disperse heat transferred from the first heat transfer member 440 in a horizontal direction. By redistributing heat transferred vertically from the main heat generating element to the first heat transfer member 440 in a horizontal direction, heat dissipation performance of the printed circuit board assembly 1200 may be enhanced.

According to an example, the cover portions 1231b, 1231c may include a shielding layer 1231b. The shielding layer 1231b may be disposed below the heat transfer layer 1231c. Unlike illustrated, the shielding layer 1231b may be disposed above the heat transfer layer 1231c. The shielding layer 1231b may have, e.g., a thermal conductivity of 300 to 400 W/mK, but the disclosure is not limited thereto. The shielding layer 1231b may have, e.g., a relatively smaller thermal conductivity compared to the heat transfer layer 1231c. The shielding layer 1231b may, e.g., include copper. However, the disclosure is not limited thereto. According to an example, the heat transfer layer 1231c and the shielding layer 1231b may be laminated together.

According to an example, the support portion 1231a may be provided to support the cover portions 1231b, 1231c. The support portion 1231a may form a side portion or side surface of the first shielding member 1231. The support portion 1231a may be disposed between the PCB 410 and the cover portions 1231b, 1231c. The support portion 1231a may include an opening having an open top. The cover portions 1231b, 1231c may be disposed to cover the opening. The support portion 1231a may be configured to shield electromagnetic waves generated from the plurality of first electronic components 421.

According to an example, the cover portions 1231b, 1231c may be formed extending from the upper surface of the first shielding member 1231. The cover portions 1231b, 1231c may be formed to extend outward from an upper portion of the support portion 1231a. The area of the cover portions 1231b, 1231c may be relatively larger than the horizontal area formed by the support portion 1231a. The cover portions 1231b, 1231c may be configured to cover at least a portion of at least one second shielding member 432 among adjacent plurality of second shielding members 432. The cover portions 1231b, 1231c may be configured to cover at least a portion of the first shielding member 1231 and at least one second shielding member 432.

According to an example, the heat transfer layer 1231c and shielding layer 1231b of the cover portions 1231b, 1231c may be formed extending from the upper surface of the first shielding member 1231. The laminated heat transfer layer 1231c and shielding layer 1231b may extend outward from the upper portion of the support portion 1231a to cover at least a portion of the upper surface of at least one second shielding member 432 among surrounding plurality of second shielding members 432.

According to an example, heat generated from the main heat generating element of the third electronic component 423 may be dissipated through a first heat dissipation path P1 and a third heat dissipation path P3. The first heat dissipation path P1 may include, e.g., a path where heat generated from the main heat generating element sequentially passes through the second heat transfer member 450 and the third shielding member 433 to be dissipated to the outside.

According to an example, the third heat dissipation path P3 may include a path where heat generated from the main heat generating element sequentially passes through the PCB 410, the first heat transfer member 440, and the first shielding member 1231 to be dissipated to the outside. The third heat dissipation path P3 may include, e.g., a path where heat is transferred from the main heat generating element to the PCB 410 and the first heat transfer member 440, and heat from the first heat transfer member 440 is dissipated horizontally through the cover portions 1231b, 1231c of the first shielding member 1231. Heat transferred from the main heat generating element may be dissipated horizontally by, e.g., the heat transfer layer 1231c of the cover portions 1231b, 1231c. Here, the horizontal direction may refer to a planar direction of the cover portions 1231b, 1231c. The cover portions 1231b, 1231c extended to cover at least one adjacent second shielding member 432 may provide a wider third heat dissipation path P3 compared to the second heat dissipation path P2 of FIG. 5. By extending the area of the cover portions 1231b, 1231c, the printed circuit board assembly 1200 may be more efficiently cooled. In the disclosure, by additionally configuring the third heat dissipation path P3 as well as the first heat dissipation path P1, heat dissipation performance of the main heat generating element may be enhanced.

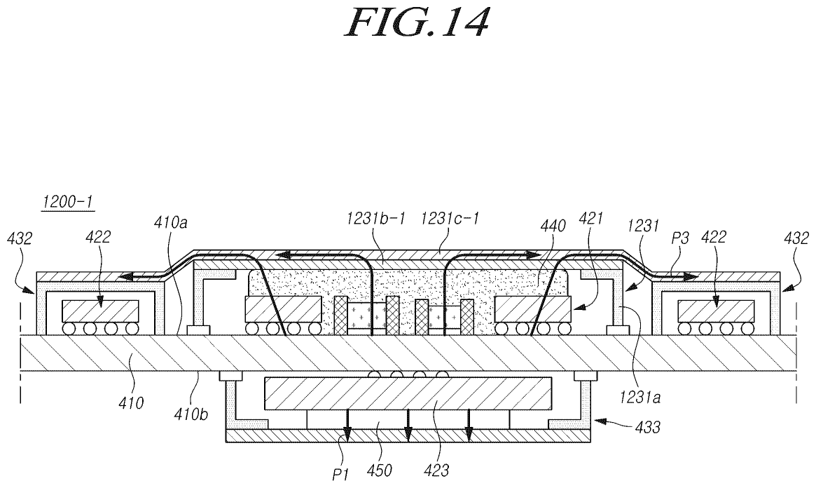

FIG. 14 is a cross-sectional view illustrating a printed circuit board assembly according to an embodiment of the disclosure.

FIG. 14 may be a cross-sectional view taken along line B-B′ in the printed circuit board assembly 1200 of FIG. 12. The drawing illustrated in FIG. 14 is schematically illustrated for convenience of description, and the scope of rights of the disclosure is not limited to the illustrated form.

For configurations illustrated in FIG. 14 that are substantially identical or similar to configurations of the printed circuit board assembly 400 illustrated in FIG. 5, the same reference numbers are used.

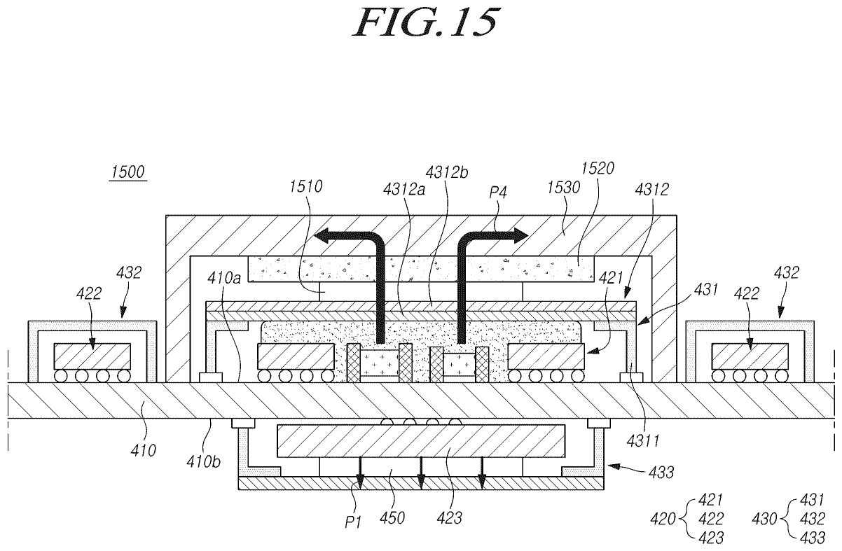

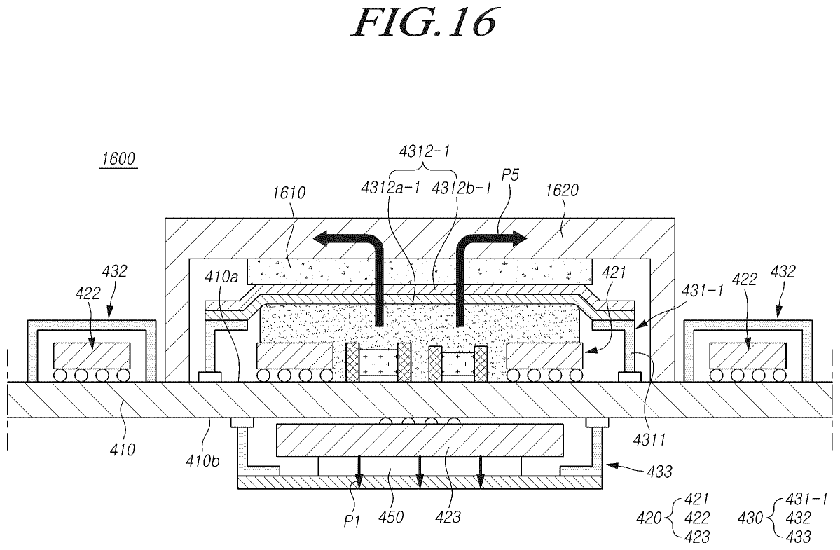

The embodiment of FIG. 14 may be selectively combined with the embodiments of FIGS. 4 to 6, 7A, 7B, 8 to 10, 11A, 11B, 12, and 13. The embodiments of FIG. 14 may be selectively combined with the embodiments of FIGS. 15 and 16.

Referring to FIG. 14, a printed circuit board assembly 1200-1 may include a first shielding member 1231.

According to an example, the first shielding member 1231 may include a support portion 1231a and cover portions 1231b-1, 1231c-1. The support portion 1231a and the cover portions 1231b-1, 1231c-1 may be configured to protect the plurality of first electronic components 421 disposed within the first shielding member 1231 from external impacts and to efficiently dissipate heat.

According to an example, the cover portions 1231b-1, 1231c-1 may be configured to be thermally compressible. The cover portions 1231b-1, 1231c-1 may have a non-restorable property that does not return to its original shape after thermal deformation. In case that heat above a predetermined temperature is applied to the cover portions 1231b-1, 1231c-1, the cover portions 1231b-1, 1231c-1 may be plastically deformed. The cover portions 1231b-1, 1231c-1 may simultaneously have shielding and heat dissipation functions.

According to an example, the cover portions 1231b-1, 1231c-1 may include a heat transfer layer 1231c-1. The heat transfer layer 1231c-1 may, e.g., form an upper surface of the cover portions 1231b-1, 1231c-1. The heat transfer layer 1231c-1 may have, e.g., a thermal conductivity of up to 1400 W/mK, but the disclosure is not limited thereto. For example, the heat transfer layer 1231c-1 may be a graphite sheet. However, the disclosure is not limited thereto.

According to an example, the heat transfer layer 1231c-1 may disperse heat transferred from the first heat transfer member 440 in a horizontal direction. By redistributing heat transferred vertically from the third electronic component 423 to the first heat transfer member 440 in a horizontal direction, heat dissipation performance of the printed circuit board assembly 1200-1 may be enhanced.

According to an example, the cover portions 1231b-1, 1231c-1 may include a shielding layer 1231b-1. The shielding layer 1231b-1 may be disposed below the heat transfer layer 1231c-1. Unlike illustrated, the shielding layer 1231b-1 may be disposed above the heat transfer layer 1231c-1. The shielding layer 1231b-1 may have, e.g., a thermal conductivity of 300 to 400 W/mK, but the disclosure is not limited thereto. The shielding layer 1231b-1 may have, e.g., a relatively smaller thermal conductivity compared to the heat transfer layer 1231c-1. The shielding layer 1231b-1 may, e.g., include copper. However, the disclosure is not limited thereto. According to an example, the heat transfer layer 1231c-1 and the shielding layer 1231b-1 may be laminated together.

According to an example, the support portion 1231a may be provided to support the cover portions 1231b-1, 1231c-1. The support portion 1231a may form a side portion or side surface of the first shielding member 1231. The support portion 1231a may be disposed between the PCB 410 and the cover portions 1231b-1, 1231c-1. The support portion 1231a may include an opening having an open top. The cover portions 1231b-1, 1231c-1 may be disposed to cover the opening. The support portion 1231a may be configured to shield electromagnetic waves generated from the plurality of first electronic components 421.

According to an example, the cover portions 1231b-1, 1231c-1 may be formed extending from the upper surface of the first shielding member 1231. The area of the cover portions 1231b-1, 1231c-1 may be relatively larger than the horizontal area formed by the support portion 1231a. The cover portions 1231b-1, 1231c-1 may be configured to cover at least a portion of at least one second shielding member 432 among adjacent plurality of second shielding members 432. The cover portions 1231b-1, 1231c-1 may be configured to cover at least a portion of the first shielding member 1231 and at least one second shielding member 432.

According to an example, the heat transfer layer 1231c-1 of the cover portions 1231b-1, 1231c-1 may be formed extending from the upper surface of the first shielding member 1231. The size of the heat transfer layer 1231c-1 may be larger than the size of the shielding layer 1231b-1. The heat transfer layer 1231c-1 may be disposed to extend outward relative to the shielding layer 1231b-1. Out of the laminated heat transfer layer 1231c-1 and shielding layer 1231b-1, only the heat transfer layer 1231c-1 may extend outward from the upper portion of the support portion 1231a to cover at least a portion of the upper surface of at least one second shielding member 432 among surrounding plurality of second shielding members 432. Unlike illustrated in FIG. 13, in the embodiment of FIG. 14, the shielding layer 1231b-1 may be disposed only on an upper portion of the support portion 1231a.

According to an example, heat generated from the main heat generating element of the third electronic component 423 may be dissipated through a first heat dissipation path P1 and a third heat dissipation path P3. The first heat dissipation path P1 may include, e.g., a path where heat generated from the main heat generating element sequentially passes through the second heat transfer member 450 and the third shielding member 433 to be dissipated to the outside.

According to an example, the third heat dissipation path P3 may include a path where heat generated from the main heat generating element sequentially passes through the PCB 410, the first heat transfer member 440, and the first shielding member 1231 to be dissipated to the outside. The third heat dissipation path P3 may include, e.g., a path where heat is transferred from the main heat generating element to the PCB 410 and the first heat transfer member 440, and heat from the first heat transfer member 440 is dissipated horizontally through the cover portions 1231b-1, 1231c-1 of the first shielding member 1231. Heat transferred from the main heat generating element may be dissipated horizontally by, e.g., the heat transfer layer 1231c-1 of the cover portions 1231b-1, 1231c-1. Here, the horizontal direction may refer to a planar direction of the cover portions 1231b-1, 1231c-1. The cover portions 1231b-1, 1231c-1 (especially the heat transfer layer 1231c-1) extended to cover at least one adjacent second shielding member 432 may provide a wider third heat dissipation path P3 compared to the second heat dissipation path P2 of FIG. 5. By extending the area of the heat transfer layer 1231c-1, the printed circuit board assembly 1200-1 may be more efficiently cooled. In the disclosure, by additionally configuring the third heat dissipation path P3 as well as the first heat dissipation path P1, heat dissipation performance of the main heat generating element may be enhanced.

FIG. 15 is a cross-sectional view illustrating a printed circuit board assembly according to an embodiment of the disclosure.

For configurations illustrated in FIG. 15 that are substantially identical or similar to configurations of the printed circuit board assembly 400 illustrated in FIG. 5, the same reference numbers are used.

The embodiment of FIG. 15 may be selectively combined with the embodiments of FIGS. 4 to 6, 7A, 7B, 8 to 10, 11A, 11B, and 12 to 14. The embodiment of FIG. 15 may be selectively combined with the embodiment of FIG. 16.

Referring to FIG. 15, a printed circuit board assembly 1500 may further include a third heat transfer member 1510, a fourth heat transfer member 1520, and a rear cover 1530.

According to an example, the third heat transfer member 1510 may be disposed on the first shielding member 431. The third heat transfer member 1510 may be disposed to contact an upper surface of the first shielding member 431. The third heat transfer member 1510 may have, e.g., substantially the same or similar configuration as the second heat transfer member 450.

According to an example, the fourth heat transfer member 1520 may be disposed on the third heat transfer member 1510. The fourth heat transfer member 1520 may be disposed to contact an upper surface of the third heat transfer member 1510. The fourth heat transfer member 1520 may include a metal material.

According to an example, the rear cover 1530 may be disposed to cover the first shielding member 431, the third heat transfer member 1510, and the fourth heat transfer member 1520. The rear cover 1530 may contact the fourth heat transfer member 1520. The rear cover 1530 may have thermal conductivity similar to or lower than the first heat transfer member 440, the third heat transfer member 1510, or the fourth heat transfer member 1520. The rear cover 1530 may, e.g., form an outermost portion of the electronic device 200 in case that the printed circuit board assembly 1500 is mounted in an electronic device (e.g., the electronic device 200 of FIG. 2A), or may be a configuration most adjacent to the outermost portion of the electronic device 200.

According to an example, heat generated from the main heat generating element of the third electronic component 423 may be dissipated through a first heat dissipation path P1 and a fourth heat dissipation path P4. The first heat dissipation path P1 may include, e.g., a path where heat generated from the main heat generating element sequentially passes through the second heat transfer member 450 and the third shielding member 433 to be dissipated to the outside.

According to an example, the fourth heat dissipation path P4 may include a path where heat generated from the main heat generating element sequentially passes through the PCB 410, the first heat transfer member 440, the first shielding member 1231, the third heat transfer member 1510, the fourth heat transfer member 1520, and the rear cover 1530 to be dissipated to the outside. The fourth heat dissipation path P4 may include, e.g., a path where heat is transferred from the main heat generating element to the PCB 410 and the first heat transfer member 440, and heat from the first heat transfer member 440 passes through the first shielding member 1231, then through the third heat transfer member 1510, the fourth heat transfer member 1520, and the rear cover 1530 to be dissipated to the outside. Heat transferred from the main heat generating element may be dissipated along, e.g., the surface of the rear cover 1530.

FIG. 16 is a cross-sectional view illustrating a printed circuit board assembly according to an embodiment of the disclosure.

For configurations illustrated in FIG. 16 that are substantially identical or similar to configurations of the printed circuit board assembly 400 illustrated in FIG. 5, the same reference numbers are used.

The embodiment of FIG. 16 may be selectively combined with the embodiments of FIGS. 4 to 6, 7A, 7B, 8 to 10, 11A, 11B, and 12 to 15.

Referring to FIG. 16, a printed circuit board assembly 1600 may include a first shielding member 431-1.

According to an example, the first shielding member 431-1 may include a support portion 4311 and a cover portion 4312-1. According to an example, the cover portion 4312-1 may be formed such that at least a portion protrudes upward. Here, upward may refer to a direction from the cover portion 4312-1 toward the third heat transfer member 1610. In case of attempting to secure a heat transfer path by contacting the cover portion 4312-1 with another heat transfer member (e.g., the third heat transfer member 1610 or rear cover 1620), the shape of the cover portion 4312-1 may be intentionally protruded.

According to an example, the cover portion 4312-1 may include a shielding layer 4312a-1 and a heat transfer layer 4312b-1. For example, the shielding layer 4312a-1 may be formed such that at least a portion protrudes upward. For example, the heat transfer layer 4312b-1 may be formed such that at least a portion protrudes upward.

According to an example, the printed circuit board assembly 1600 may further include a third heat transfer member 1610 and a rear cover 1620.

According to an example, the third heat transfer member 1610 may be disposed on the first shielding member 431. The third heat transfer member 1610 may be disposed to contact an upper surface of the first shielding member 431. The third heat transfer member 1610 may have, e.g., substantially the same or similar configuration as the second heat transfer member 450.

According to an example, the rear cover 1620 may be disposed to cover the first shielding member 431 and the third heat transfer member 1610. The rear cover 1620 may contact the third heat transfer member 1610. The rear cover 1620 may have thermal conductivity similar to the first heat transfer member 440 or the third heat transfer member 1610.

According to an example, heat generated from the main heat generating element of the third electronic component 423 may be dissipated through a first heat dissipation path P1 and a fifth heat dissipation path P5. The first heat dissipation path P1 may include, e.g., a path where heat generated from the main heat generating element sequentially passes through the second heat transfer member 450 and the third shielding member 433 to be dissipated to the outside.

According to an example, the fifth heat dissipation path P5 may include a path where heat generated from the main heat generating element sequentially passes through the PCB 410, the first heat transfer member 440, the first shielding member 431-1, the third heat transfer member 1610, and the rear cover 1620 to be dissipated to the outside. The fifth heat dissipation path P5 may include, e.g., a path where heat is transferred from the main heat generating element to the PCB 410 and the first heat transfer member 440, and heat from the first heat transfer member 440 passes through the first shielding member 431-1, then through the third heat transfer member 1610 and the rear cover 1620 to be dissipated to the outside. Heat transferred from the main heat generating element may be dissipated along, e.g., the surface of the rear cover 1620.

A printed circuit board assembly 400 according to an embodiment may include a PCB 410, a plurality of electronic components 420 configured to be mounted on a first surface 410a of the PCB 410, a first shielding member 431 configured to cover the plurality of electronic components 420, and a heat transfer member 440 received within the first shielding member 431, having at least a portion disposed in a space formed between the plurality of electronic components 420, and configured to be thermally deformable.

According to an embodiment, the heat transfer member 440 may be configured to have a glass transition temperature of 40 degrees Celsius or higher.

According to an embodiment, the printed circuit board assembly 400 may further include a main heat generating element 423 mounted on a portion corresponding to the heat transfer member 440 on a second surface 410b opposite to the first surface 410a of the PCB 410.

According to an embodiment, the first shielding member 431 may include a graphite sheet forming at least a portion of an upper surface.

According to an embodiment, the printed circuit board assembly 400 may further include at least one second shielding member 432 disposed around the first shielding member 431. The graphite sheet may be configured to extend from the upper surface of the first shielding member 431 to cover the at least one second shielding member 432.

According to an embodiment, the heat transfer member 440 may include a rubber material.

According to an embodiment, the heat transfer member 440 may include a phase change material (PCM)-based material.

An electronic device according to an embodiment may include a housing 210, a display 201, and a printed circuit board assembly 400 disposed within the housing 210. The printed circuit board assembly 400 may include a PCB 410, a plurality of electronic components 420 mounted on a first surface 410a of the PCB 410, a first shielding member 431 provided to cover the plurality of electronic components 420, and a heat transfer member 440 received within the first shielding member 431, having at least a portion disposed in a space formed between the plurality of electronic components 420, and configured to be thermally deformable.

According to an embodiment, the heat transfer member 440 may have a glass transition temperature of 40 degrees Celsius or higher.

According to an embodiment, it may further include a main heat generating element mounted on a portion corresponding to the heat transfer member 440 on a second surface 410b opposite to the first surface 410a of the PCB 410.

According to an embodiment, the first shielding member 431 may include a graphite sheet forming at least a portion of an upper surface.

According to an embodiment, the printed circuit board assembly 400 may further include at least one second shielding member 432 disposed around the first shielding member 431.

The graphite sheet is configured to extend from the upper surface of the first shielding member 431 to cover the at least one second shielding member 432.

According to an embodiment, the heat transfer member 440 may include a rubber-based material.

According to an embodiment, the heat transfer member 440 may include a phase change material (PCM)-based material.

According to an embodiment, the first surface 410a may be a surface facing the display 201.

A manufacturing method for a printed circuit board assembly according to an embodiment may include a process of disposing a heat transfer member 440 configured to be thermally deformable on a plurality of electronic components 420 mounted on a PCB 410, a process of disposing a first shielding member 431 to cover the heat transfer member 440 and the plurality of electronic components 420, and a process of an upper jig including a heating block pressing the first shielding member 431.

According to an embodiment, a glass transition temperature of the heat transfer member 440 may be 40 degrees Celsius or higher.

According to an embodiment, the heating block is at 125 degrees Celsius to 135 degrees Celsius, and the upper jig may press the first shielding member 431 for 5 seconds or more.

According to an embodiment, in the process of the first shielding member 431 covering the heat transfer member 440 and the plurality of electronic components 420, a portion of an upper surface of the first shielding member 431 may be configured to protrude upward.

According to an embodiment, in case that the upper surface of the first shielding member 431 is pressed by the heating block, the protruding portion of the upper surface of the first shielding member 431 is pressed and the heat transfer member 440 may permeate into spaces between the plurality of electronic components 420.

As used herein, each of such phrases as “A or B,” “at least one of A and B,” “at least one of A or B,” “A, B, or C,” “at least one of A, B, and C,” and “at least one of A, B, or C,” may include all possible combinations of the items enumerated together in a corresponding one of the phrases. As used herein, the term ‘and/or’ should be understood as encompassing any and all possible combinations by one or more of the enumerated items. As used herein, the terms “include,” “have,” and “comprise” are used merely to designate the presence of the feature, component, part, or a combination thereof described herein, but use of the term does not exclude the likelihood of presence or adding one or more other features, components, parts, or combinations thereof. As used herein, the terms “first” and “second” may modify various components regardless of importance and/or order and are used to distinguish a component from another without limiting the components.

As used herein, the terms “configured to” may be interchangeably used with the terms “suitable for,” “having the capacity to,” “designed to,” “adapted to,” “made to,” or “capable of” depending on circumstances. The term “configured to” does not essentially mean “specifically designed in hardware to.” Rather, the term “configured to” may mean that a device can perform an operation together with another device or parts. For example, a ‘device configured (or set) to perform A, B, and C’ may be a dedicated device to perform the corresponding operation or may mean a general-purpose device capable of various operations including the corresponding operation.

Meanwhile, the terms “upper side,” “lower side,” and “front and rear directions” used in the disclosure are defined with respect to the drawings, and the shape and position of each component are not limited by these terms.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. A printed circuit board assembly comprising:
a printed circuit board (PCB);
a plurality of electronic components configured to be mounted on a first surface of the PCB;
a first shielding member configured to cover the plurality of electronic components; and
a heat transfer member received within the first shielding member, having a portion disposed in a space formed between the plurality of electronic components, and configured to be thermally deformable.

2. The printed circuit board assembly of claim 1, wherein the heat transfer member is configured to have a glass transition temperature of 40 degrees Celsius or higher.

3. The printed circuit board assembly of claim 1, further comprising:
a main heat generating element mounted on a portion corresponding to the heat transfer member on a second surface opposite to the first surface of the PCB.

4. The printed circuit board assembly of claim 1, further comprising:
at least one second shielding member disposed around the first shielding member,
wherein the first shielding member includes a graphite sheet extending from an upper surface of the first shielding member and configured to cover the at least one second shielding member.

5. The printed circuit board assembly of claim 1, wherein the heat transfer member includes at least one of a rubber material or a phase change material (PCM)-based material.

6. An electronic device comprising:
a housing;
a display; and
a printed circuit board assembly disposed within the housing,
wherein the printed circuit board assembly includes:
a printed circuit board (PCB),
a plurality of electronic components mounted on a first surface of the PCB,
a first shielding member provided to cover the plurality of electronic components, and
a heat transfer member received within the first shielding member, having at least a portion disposed in a space formed between the plurality of electronic components, and configured to be thermally deformable.

7. The electronic device of claim 6, wherein the heat transfer member has a glass transition temperature of 40 degrees Celsius or higher.

8. The electronic device of claim 6, further comprising:
a main heat generating element mounted on a portion corresponding to the heat transfer member on a second surface opposite to the first surface of the PCB.

9. The electronic device of claim 6, wherein the first shielding member includes a graphite sheet.

10. The electronic device of claim 9,
wherein the printed circuit board assembly further includes at least one second shielding member disposed around the first shielding member, and
wherein the graphite sheet extends from an upper surface of the first shielding member and is configured to cover the at least one second shielding member.

11. The electronic device of claim 6, wherein the heat transfer member includes at least one of a rubber-based material or a phase change material (PCM)-based material.

12. A manufacturing method of a printed circuit board assembly, the manufacturing method comprising:
disposing a heat transfer member configured to be thermally deformable on a plurality of electronic components mounted on a printed circuit board (PCB);
disposing a first shielding member to cover the heat transfer member and the plurality of electronic components; and
pressing the first shielding member with an upper jig including a heating block.

13. The manufacturing method of claim 12, wherein a glass transition temperature of the heat transfer member is 40 degrees Celsius or higher.

14. The manufacturing method of claim 12,
wherein the heating block is at 125 degrees Celsius to 135 degrees Celsius, and
wherein in pressing the first shielding member with the upper jig, the upper jig presses the first shielding member for 5 seconds or more.

15. The manufacturing method of claim 12,
wherein in covering the heat transfer member and the plurality of electronic components with the first shielding member, a portion of an upper surface of the first shielding member is disposed to protrude upward, and
wherein in case that the upper surface of the first shielding member is pressed by the heating block, a protruding portion of the upper surface of the first shielding member is pressed and the heat transfer member permeates into a space between the plurality of electronic components.
